(19) United States
(12) Patent Application Publication
(10) Pub. No.: US 2017/0117174 A1
(43) Pub. Date: Apr. 27, 2017

(54) ELECTRO-STATIC CHUCK WITH RADIOFREQUENCY SHUNT

(71) Applicant: EVATEC AG, Trübbach (CH)

(72) Inventors: Juergen WEICHART, Balzers (LI); Kay VIEHWEGER, Dresden (DE)

(73) Assignee: EVATEC AG, Trübbach (CH)

(21) Appl. No.: 15/315,219

(22) PCT Filed: Jun. 15, 2015
(86) PCT No.: PCT/CH2015/000090

§ 371 Date: Nov. 30, 2016

Related U.S. Application Data
(60) Provisional application No. 62/013,047, filed on Jun. 17, 2014.

(51) Int. Cl. H01L 21/683

(52) U.S. Cl. CPC H01L 21/6833

(57) ABSTRACT

An electrostatic chuck (ESC) exhibits a ceramic body with planar electrodes applied as bottom and top electrodes connected by vias through the ceramic body and a conducting layer on top of said ceramic body. A conducting current path is being arranged around the edge of the ESC acting as an RF shunt connecting the RF chuck body with the back side of a substrate when arranged on said conducting top layer. Preferably, this RF shunt is construed as a conductive ring around the edges of the ESC, the preferred material being metal, noble metal or a carbon based conductive film

The present invention relates to an ESC RF Shunt to enable dechucking from an electrostatic chuck (ESC) working in conditions with high RF voltages.

### TECHNICAL BACKGROUND

ESCs are commonly used for holding silicon wafers during semiconductor manufacturing processes. They usually comprise a metal baseplate and a thin dielectric layer; the metal base-plate is maintained at a high-voltage relative to the wafer, and so an electrostatic force clamps the wafer to it. Electrostatic chucks may have pins, or mesas, the height of which is included in the reported dielectric thickness.

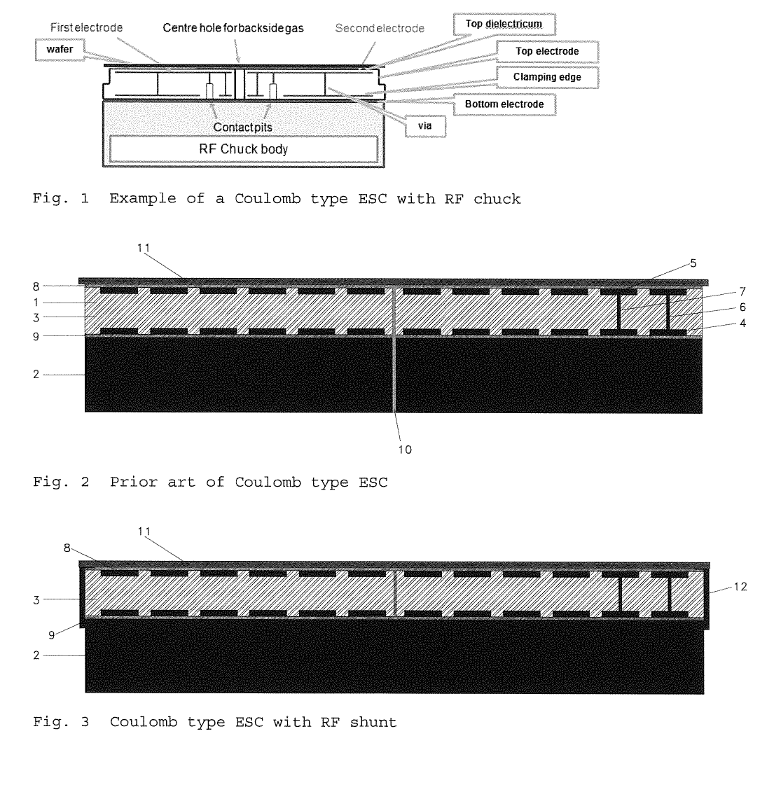

There are two types of ESCs to control the temperature when processing substrates like Si wafer or glass substrates with thinned Si wafers mounted on these: The Johnson-Rahbeck type where the top dielectric layer has a residual conductivity and the Coulomb type, where the top dielectric layer is highly resistive. The Coulomb type has the advantage of having a low leakage current from the electrodes and that the grip force is almost not affected by temperature. One possible embodiment of a Coulomb type ESC is shown in FIG. 1. The way how to build and apply these ESCs is described in US20060043065(A1), US 2006164785 (Semco), US2003-0095370A1, US_20130279066_A1 and other documents. In US_20130284709_A1 the application of an inner and an outer RF electrode embedded in the ESC dielectric puck with a low RF loss are disclosed.

In many applications Coulomb type ESCs are used in process chambers, where the substrate is processed with a radio frequency (RF). Especially when high RF voltages are applied it was observed that charges accumulate on the top dielectric layer of the ESC. In this case there is the risk that the substrate is not released after processing.

De-chucking strategies after the application of RF processes are described in U.S. Pat. No. 6,307,728B1, U.S. Pat. No. 5,933,314 and U.S. Pat. No. 5,835,333. Here offset voltages are used to balance out the charge induced due to the self-bias voltage in RF discharges. U.S. Pat. No. 5,103,367 proposes to use a third electrode as a reference to sense the required grip and release forces on the first and the second electrode.

U.S. Pat. No. 5,325,261 describes to use the mechanical distance of the substrate measured as a capacity to adjust the required release voltage of the ESC. Edge rings around the substrate are proposed in WO2011063084. These are usually insulating and provide a gap in the height between the substrate and the lower edge ring level.

Dielectric collar rings are described in WO1999014796(A1) and WO2011063084(A2), these being defined to have a low conductivity. A second RF electrode, embedded in dielectric material and coupled to the RF source by a divider circuit is published in WO2013062833(A1). An electrode larger than the substrate and a ceramic ring protecting the wafer edge and still allowing a good coupling of the RF field is claimed in US20030211757(A1).

### DRAWBACKS OF PRIOR ART

It was observed that the de-chucking of processed substrates from Coulomb type ESCs is not guaranteed if high RF voltages are applied to the assembly. This sticking problem was observed for the RF bias application in Sputtering and ICP etch, where high plasma densities are present. However in some cases there was even sticking observed with RF only, which means without process gas, without plasma and without applying an ESC voltage. The sticking is accumulative; it may happen on wafer 1, 2, 5, or 15 in a sequence of otherwise identical substrates during the same process. The sticking is related to RF voltage and not to RF current: For example processes with a high RF voltage, like 1000V peak-peak lead to an early and the strongest sticking, already wafer no. 1 or 2 in a sequence will not release safely. In contrary processes with a high RF current and comparably lower voltage, like an Inductively Coupled Plasma (ICP) show a delay in the accumulation of charges and therefore to later sticking, which may be on substrate 3 to 8.

### DESCRIPTION OF THE INVENTION

The solution described is based on a bipolar Coulomb type ESC with top and bottom dielectric, but it may be also applied to other ESC types as well.

FIG. 2 shows the prior art of an ESC (1) situated on a RF chuck body (2). The ESC (1) consists of a ceramic body (3), on which planar electrodes have been applied as bottom (4) and top electrodes (5). The electrodes are interdigitated and driven by opposite polarities to enable bipolar chucking. Bottom (4) and top electrodes (5) are connected by vias (6, 7) through the ceramic body for both polarities. These vias are shown exemplarily only. The RF capacitively couples from the RF chuck to the bottom electrodes (4). Through the vias the RF power drives the top electrodes (5), from where it couples capacitively to the substrate (11). In the centre of the RF chuck body and the ESC a back side gas hole (10) is provided to enable a good thermal contact between the ESC and the substrate (11) by a back side gas cushion.

The solution to de-chucking problems with the ESC with high RF voltages, called sticking, is to apply an RF shunt (12) at the outer edge of the ESC as sketched in FIG. 3. This shunt connects the RF chuck body (2) with the back side of the substrate (11). It is made of a material with good conductivity. The shunt can be a sputtered metal, like Al, a screen printed or otherwise applied metal film. Preferably a noble metal, like Pt, is applied. Alternatively a carbon based film may be applied, which provides the lowest friction and still good conductivity.

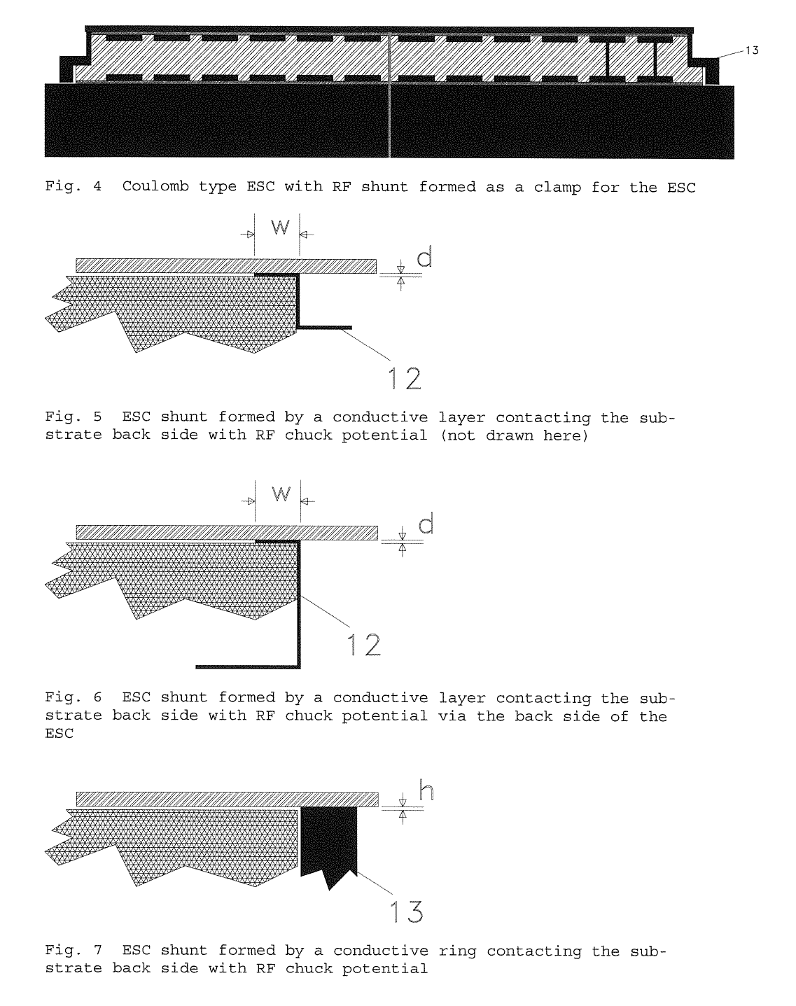

It is a common practice to make the ESC an exchangeable part on the chuck top. In this case a clamp ring (13) can be applied to fix the ESC on the chuck top as sketched in FIG. 4. The clamp is designed so that it contacts the wafer back side to work as an RF shunt. It is preferably made of metal. Since the RF shunt may get in contact with the plasma above the chuck it is preferably made of a material with a low sputter yield, which is also compatible with the subsequent process steps. A ring made of Ti e.g. would fulfil these requirements. However in some cases it may be even requested to apply a film on the RF shunt ring having the lowest risk of contamination and the lowest friction against substrate movements when this is attracted by the ESC force.

FIG. 5 shows the ESC shunt formed by a conductive layer (12) contacting the substrate back side with RF chuck potential. The RF chuck is not drawn here. This layer has a thickness d in the range between 0.1 and 50 μm, preferably in the range between 0.5 and 10 μm. The width w of the layer coated onto the ESC top from the outer rim inwards is in the range between 0.1 and 5 mm, preferably between 1 and 3 mm. Alternatively the conductive layer can be coated around the ESC edge (FIG. 6), so that it contacts the metal part of the RF chuck, where it sits on.

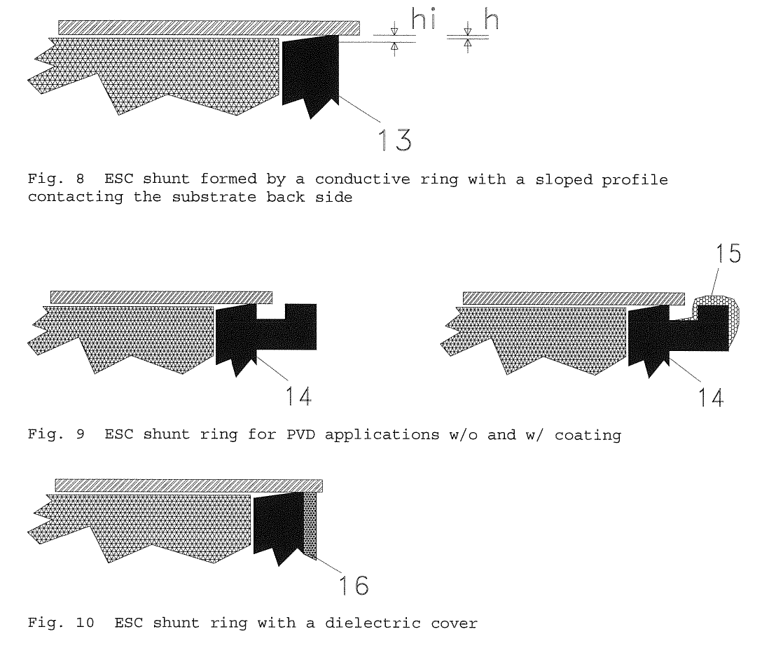

A conductive ring (13) can provide the same function as the layer (12). In addition this ring may be used to clamp the ESC on the RF chuck (FIG. 7). To ensure a good contact the ring (13) has to be designed slightly higher than the ESC top level. The height of the ring above the ESC top level h is

0<h<0.1mm

The ring may be spring loaded. Since the inner edge of the ring may damage the substrate when this is attracted by the ESC it is further proposed to use a profiled shunt ring as shown in FIG. 8, where the inner height hᵢ of the ring is below the ESC top level and the outer height h is above.

The solutions designed in FIGS. 7 and 8 are preferred for etch applications, where the shunt ring should not be exposed to the process plasma. When the ESC is applied for sputtering or PVD processes with a high RF bias the shunt ring may have the additional function as a protecting shield from the material deposited.

FIG. 9 shows the design of a preferred ESC shunt ring (14) for PVD applications without and with coating (15). This design may however also be used for etch applications.

The RF shunt may also be realized by an embedded structure providing electrical contact from the substrate and to the RF chuck, which may be otherwise covered by a dielectric material (16). FIG. 10 shows the RF shunt ring with a dielectric cover, however the latter may also be applied to a layer like in FIG. 5 or 6.

1) An electrostatic chuck (ESC) (1) to be arranged on a RF chuck body (2), said ESC comprising a ceramic body (3) with planar electrodes applied as bottom (4) and top electrodes (5) connected by vias (6, 7) through the ceramic body; a conducting layer (8) applied on top of said ceramic body (3), characterized by a conducting current path arranged around the edge of the ESC acting as RF shunt (12) connecting the RF chuck body (2) with the back side of a substrate (11) when arranged on conducting layer (8).

2) The ESC according to claim 1, characterized in that the conducting current path is construed as a conductive ring.

3) The ESC according to claim 1, characterized in that the conducting current path is made of metal.

4) The ESC according to claim 3, characterized in that the conducting current path is made of sputtered metal, a screen printed or otherwise applied metal film.

5) The ESC according to claim 3, characterized in that the conducting current path is made of a noble metal, like Pt

6) The ESC according to claim 2, characterized in that the conducting current path is made of a carbon based film.

7) The ESC according to claim 6, characterized in that the conducting current path is made of DLC (diamond like carbon).

8) The ESC according to claim 3, characterized in that the conducting current path is made of one of Al, Ti, Ta.

9) The ESC according to claim 2, characterized in that the conductive ring is construed as clamping ring (13) to clamp the ESC to the RF chuck body.

10) The ESC according to claim 3, characterized in that the conductive ring is realized as an embedded structure providing electrical contact from the substrate and to the RF chuck and is covered by a dielectric material.
